(19) United States
(12) Patent Application Publication
(10) Pub. No.: US 2026/0059717 A1
(43) Pub. Date: Feb. 26, 2026

(54) FLOATING MANIFOLD ASSEMBLY FOR LIQUID-COOLING CONNECTIONS

(71) Applicant: Aivres Systems Inc., Fremont, CA (US)

(72) Inventor: Yu-Ta LIN, New Taipei City (TW)

(21) Appl. No.: 19/377,164

(22) Filed: Nov. 3, 2025

(51) Int. Cl. H05K 7/20; F28F 9/02

(52) U.S. Cl. CPC H05K 7/20781; F28F 9/0258

(57) ABSTRACT

A manifold assembly mounts within an electronic equipment chassis to couple liquid-cooling fittings while accommodating blind mating. The assembly includes a manifold base with upstanding posts, a manifold body captured between the base and a top assembly, and at least one side-port coupling interface configured to accept a mating fitting. The manifold body has through-holes receiving the posts, and the top assembly retains the manifold body while permitting controlled float relative to the base in a horizontal direction and in a vertical direction within an enclosure formed by the base and the top assembly. The controlled float absorbs manufacturing and assembly tolerances, reducing insertion force and protecting sealing surfaces during engagement.

### TECHNICAL FIELD

This disclosure relates to thermal management of electronic equipment. More particularly, it concerns manifold structures used in liquid-cooling systems for server and rack hardware.

### BACKGROUND

Modern data-center servers increasingly employ direct-to-device liquid cooling. In a typical rack, coolant is routed from rack-side plumbing to server-side cold plates through flexible hoses and quick-connect fittings. For service, a technician slides the server chassis out on rails; the liquid connections at the rear separate, and when the server is reinserted the couplings must re-engage without visual access, i.e., in a blind-mating condition. As server interiors have become denser, manufacturing and assembly tolerances accumulate across rails, chassis, brackets, manifolds, hose runs, and connector supports. Small lateral, angular, or axial misalignments raise insertion forces, cause stubbing or cross-loading, and can damage seals such as O-rings, increasing leakage risk and reducing connector life.

Conventional designs often fasten the rack- or server-side manifold rigidly to the chassis. Such fixed mounting lacks flexibility to absorb the tolerance stack-up and motion during chassis extraction and reinsertion. Technicians must compensate by manual realignment or repeated attempts, which lengthens service time and can twist or buckle hoses, increasing flow resistance and stressing fittings. Many existing manifold mounts also require tools for removal or repositioning, complicating field replacement or bypass operations and extending downtime. Accordingly, there is a need for a server-side manifold arrangement that tolerates blind mating in confined rack spaces by providing controlled, multi-axis float to self-align couplings while protecting seals, reducing insertion force, and enabling tool-less service.

### SUMMARY

Implementations described herein relate to mechanical systems and fluid-handling assemblies for electronic equipment. In particular, the subject matter concerns structures, devices, and methods for a floating manifold assembly configured to mount within a chassis and couple liquid-cooling fittings. The features are embodied as physical components and subassemblies (e.g., molded or machined parts, springs, and latches) and corresponding methods of assembly, installation, and use; no computer program is required to practice the invention.

In one general aspect, a manifold assembly may include a manifold base having a plurality of upstanding posts. The manifold assembly may also include a manifold body captured between the manifold base and a top assembly, the manifold body having a plurality of through-holes for receiving the plurality of upstanding posts and at least one coupling interface at a side port to accept a mating liquid-cooling fitting. The assembly may furthermore include the top assembly coupled with the manifold base and retaining the manifold body while permitting controlled float of the manifold body relative to the manifold base in a horizontal direction and in a vertical direction within an enclosure formed by the manifold base and the top assembly. Other embodiments of this aspect include corresponding computer systems, apparatus, and computer programs recorded on one or more computer storage devices, each configured to perform the actions of the methods.

Implementations may include one or more of the following features. The manifold body may include one or more elongated side slots, and the top assembly may include one or more sliding plates each having a hook configured to releasably engage a corresponding one of the elongated side slots to provide lateral capture of the manifold body while maintaining a controlled float. The manifold base may define elongated side openings, and the hooks of the sliding plates may be configured to latch to and be released from the elongated side openings by pressure to enable tool-less removal of the top assembly from the manifold base.

The top assembly may include an upper-cover base and a pair of sliding plates biased by springs seated in the upper-cover base so as to urge the sliding plates toward opposite faces of the manifold body. The upper-cover base may include side grooves that guide translation of the sliding plates over a limited stroke and central slots that locate the springs. The top assembly may further include an outer cover having pillars received in corresponding holes of the upper-cover base to cap the top assembly without separate fasteners. The springs may apply a lateral retention force sufficient to maintain engagement between hooks of the top assembly and the manifold body during chassis extraction and reinsertion while avoiding over-constraint that would increase insertion force during blind mating.

Each of the plurality of upstanding posts of the manifold base may include a step adjacent a tip, and the top assembly may include keyhole-shaped apertures received over the plurality of upstanding posts and configured to cooperate with the steps to retain the top assembly to the manifold base and to define at least a portion of a vertical travel limit of the manifold body within the enclosure formed by the manifold base and the top assembly. The keyhole-shaped apertures may be formed in a pair of sliding plates and may be dimensioned with a neck portion and an enlarged portion to facilitate assembly over the plurality of upstanding posts and retention beneath the steps of the tips of the plurality of upstanding posts.

The manifold base and the top assembly may form an internal cavity whose vertical dimension exceeds a height of the manifold body by a designed margin to provide the vertical float within the enclosure. A radial clearance between the plurality of upstanding posts of the manifold base and the plurality of through-holes of the manifold body may be selected to provide the horizontal float to accommodate manufacturing and assembly stack-up tolerances of the liquid-cooling fittings. The at least one coupling interface at the side port of the manifold body may include a female connector geometry selected from the group consisting of an internally threaded connector, a bayonet-type connector, and a quick-connect socket configured for a sealing engagement.

The manifold assembly may include a base-retaining ring disposed in a stepped bore on an underside of the manifold base and configured to fix the manifold base to a surface of the chassis or a bracket. The controlled float may be established by clearances between the plurality of upstanding posts and the plurality of through-holes and by vertical headroom between the manifold body and the upper-cover base within the enclosure formed by the manifold base and the top assembly. The manifold body may include two opposing side ports each having a coupling interface to accept respective liquid-cooling fittings that connect, in use, to a server-side liquid-cooling loop and a rack-side liquid-cooling loop. Implementations of the described techniques may include hardware, a method or process, or a computer-readable tangible medium.

In one general aspect, the method may include mounting, to a chassis, a manifold assembly that may include a manifold base with posts, a manifold body with through-holes receiving the posts and side-port coupling interfaces, and a top assembly that retains the manifold body while allowing controlled float of the manifold body relative to the manifold base in a horizontal direction and in a vertical direction within an enclosure formed by the manifold base and the top assembly. The method may also include translating the chassis along rack rails to bring a mating liquid-cooling fitting toward one of the side-port coupling interfaces. The method may furthermore include permitting the manifold body to align with the mating liquid-cooling fitting by floating relative to the manifold base so as to reduce insertion force and protect sealing surfaces during engagement of the mating liquid-cooling fitting. Other embodiments of this aspect include corresponding computer systems, apparatus, and computer programs recorded on one or more computer storage devices, each configured to perform the actions of the methods.

Implementations may include one or more of the following features. The method may include releasing hooks of sliding plates of the top assembly from elongated openings of the manifold base by applying pressure to remove the top assembly without tools. The method may further include fixing a mating liquid-cooling fitting to one of the side-port coupling interfaces of the manifold body and translating the chassis along rack rails to bring the manifold assembly, together with the mating liquid-cooling fitting, toward a rack-side liquid-cooling interface so that the floating manifold body can self-align during blind mating. In the method, the controlled float in the horizontal direction may be established by a radial clearance between the posts and the through-holes of the manifold body, and the controlled float in the vertical direction may be established by clearances between the manifold body and the upper-cover base within the enclosure formed by the manifold base and the top assembly. The method may also include providing the top assembly with an outer cover having pillars received in corresponding holes of the upper-cover base to cap the top assembly without separate fasteners. The method may further include fixing the manifold base to the chassis using a retaining ring seated in a stepped bore of the manifold base to secure the manifold base to the chassis during chassis extraction and reinsertion

### BRIEF DESCRIPTION OF THE DRAWINGS

FIG. 1 illustrates an example server with coolant ports and manifolds.

FIG. 2 illustrates an exploded view of a floating manifold assembly, in accordance with some embodiments.

FIG. 3 illustrates an example manifold body of the floating manifold assembly, in accordance with some embodiments.

FIG. 4 illustrates an example manifold base of the floating manifold assembly, in accordance with some embodiments.

FIG. 5 illustrates an example top assembly of the floating manifold assembly, in accordance with some embodiments.

FIG. 6 illustrates an example assembly process for the floating manifold assembly, in accordance with some embodiments.

FIG. 7 illustrates example floating clearances in the floating manifold assembly, in accordance with some embodiments.

FIG. 8 illustrates an example disassembly process for the floating manifold assembly, in accordance with some embodiments.

FIGS. 9A and 9B illustrate an example base-retaining ring of the floating manifold assembly, in accordance with some embodiments.

FIG. 10 illustrates the deployment of the floating manifold assembly, in accordance with some embodiments.

FIG. 11 illustrates an example use of the floating manifold assembly, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

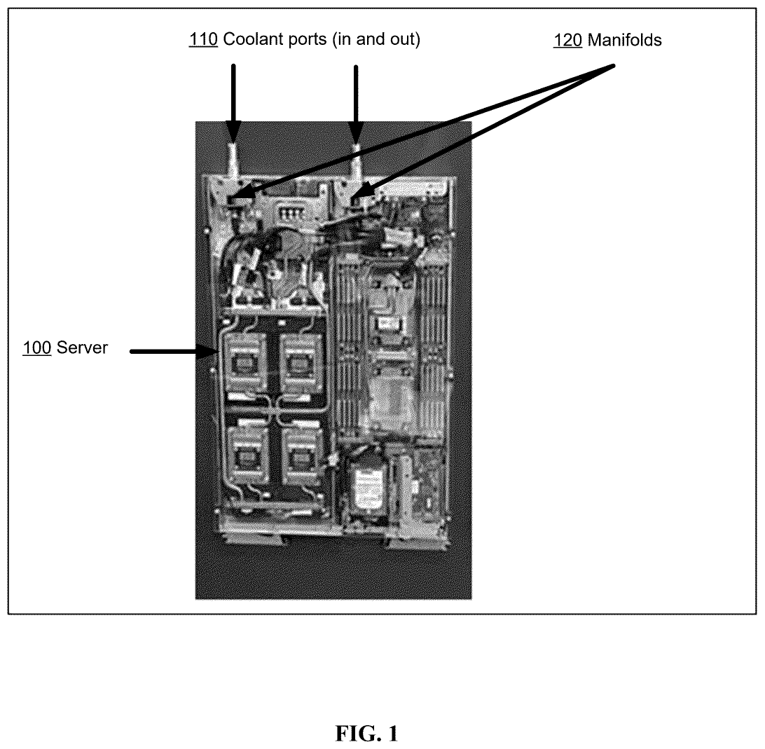

FIG. 1 illustrates an example server 100 equipped for direct-to-chip liquid cooling. As shown, the server 100 has two coolant ports 110 (one inlet port and one outlet port, usually located at the rear end of the server), the inlet port delivers cooled coolant into the server loop and the outlet returns heated coolant to the rack loop (outside of the server). The coolant ports 110 interface with manifolds 120 within the server 100 that distribute flow to internal cold plates and collect the return flow. In a typical rack installation, the manifolds 120 couple to rack-side plumbing through liquid-cooling fittings. During maintenance, the server 100 is slid out on rails and the fittings at the coolant ports 110 disconnect; when the server 100 is reinserted, the fittings re-engage in a blind-mating condition because the coolant ports 110 and manifolds 120 are not visible from the service side. In practice, tolerance stack-up across the rails, chassis, brackets, manifold mounts, and hose routing causes lateral and vertical misalignment and angular skew between the mating fittings. If the manifold is rigidly fixed, the misalignment increases insertion force, side-loads the connectors, and can damage sealing surfaces. Accordingly, this disclosure describes a floating manifold assembly that is compliant and can float in controlled horizontal and vertical directions, absorbing the accumulated tolerances and guiding the fittings into proper engagement while preserving seal integrity.

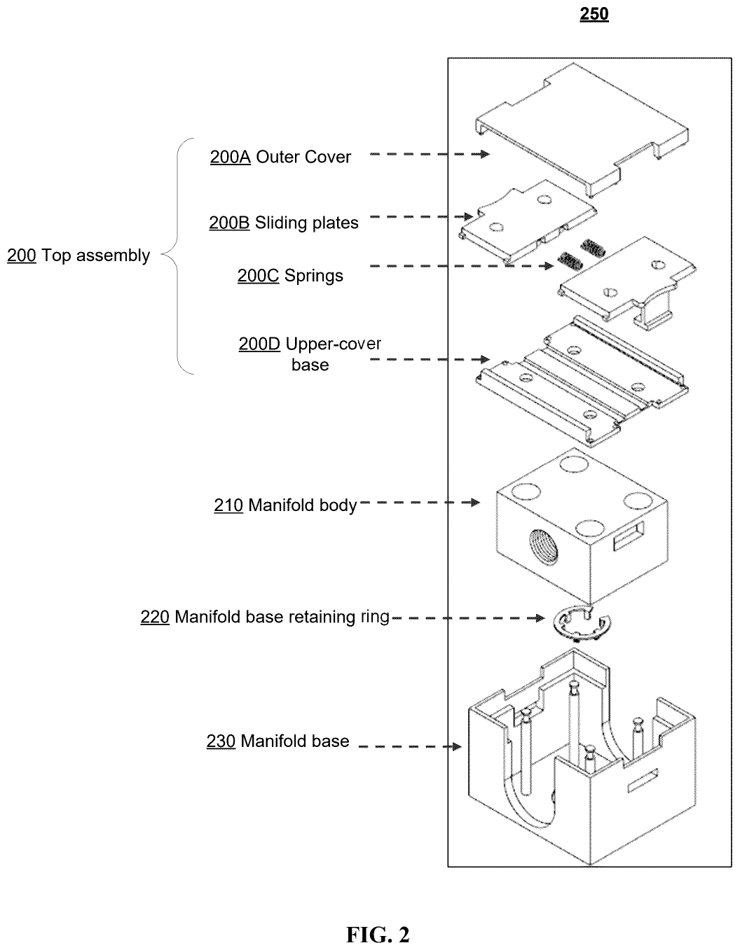

FIG. 2 illustrates an exploded view of a floating manifold assembly 250, in accordance with some embodiments. The floating manifold assembly 250 is organized around three major components: a top assembly 200, a manifold body 210, and a manifold base 230. In use, the manifold body 210 is captured between the manifold base 230 and the top assembly 200 so that it can move within controlled limits. The manifold base 230 provides primary guidance and defines travel limits, the manifold body 210 provides the fluid coupling interfaces, and the top assembly 200 retains the manifold body 210 while permitting the intentional clearances that enable horizontal and vertical float and allow tool-less assembly and disassembly of the top assembly 200 from the manifold base 230 (with the manifold body 210 remaining captured).

In this description, horizontal movement (or horizontal direction) refers to in-plane translation of the manifold body 210 relative to the manifold base 230, for example side-to-side and front-to-back within the plane of the chassis panel or manifold base 230. Vertical movement (or vertical direction) refers to out-of-plane translation of the manifold body 210 relative to the manifold base 230, for example upward and downward within the enclosure formed by the manifold base 230 and the top assembly 200

In some embodiments, the engagement between the manifold base 230 and the manifold body 210 is established partially by a plurality of upstanding posts of the manifold base 230 that pass through corresponding circular through-holes of the manifold body 210. Each post includes a step adjacent its tip. The upstanding posts guide the manifold body 210 during assembly and, together with the top assembly 200, bound the vertical movement of the manifold body 210 inside an enclosure formed by the manifold base 230 and the top assembly 200. The circular through-holes of the manifold body 210 are dimensioned with a designed radial clearance relative to the upstanding posts so that the manifold body 210 can translate side-to-side or front-to-back (i.e., in any directions horizontally) to absorb tolerance stack-up during blind mating.

The engagement between the top assembly 200 and the manifold body 210 is provided by hooks on the top assembly 200 that releasably latch into elongated side slots of the manifold body 210. This hook/slot interface captures the manifold body 210 laterally without clamping it vertically, thereby preserving the vertical clearance within the enclosure. The hook geometry also enables tool-less release when manual pressure is applied, allowing the top assembly 200 to be removed from the manifold base 230 for service.

In some embodiments, the top assembly 200 itself comprises an upper-cover base 200D, two sliding plates 200B, springs 200C that bias the sliding plates 200B, and an outer cover 200A. The upper-cover base 200D provides side grooves that guide the sliding plates 200B over a limited stroke and central slots that seat the springs 200C. Each sliding plate 200B carries keyhole-shaped apertures sized to ride over the tips of the upstanding posts of the manifold base 230; during assembly the enlarged portions of the apertures admit the post tips, and the necked portions settle beneath (via the spring-generated force) the post steps to couple the top assembly 200 to the manifold base 230 and to define a portion of the vertical travel limit of the manifold body 210. Each sliding plate 200B further includes the aforementioned hooks that releasably engage the elongated side slots of the manifold body 210. The outer cover 200A caps the top assembly 200 through pillars received in mating holes of the upper-cover base 200D, completing a captive, spring-loaded unit without separate fasteners. Collectively, these features retain the manifold body 210 while providing the designed horizontal clearances and vertical headroom that yield controlled float and facilitate blind mating.

In some embodiments, the sliding plate 200B carries a dual-edge hook, including an “outside-hook” configured to latch to the elongated side opening 410 of the manifold base 230 for tool-less base retention, and an “inside-hook” configured to latch to the elongated side slot 330 of the manifold body 210 so that, upon base release, the top assembly 200 remains coupled to the manifold body 210 as a single service subassembly

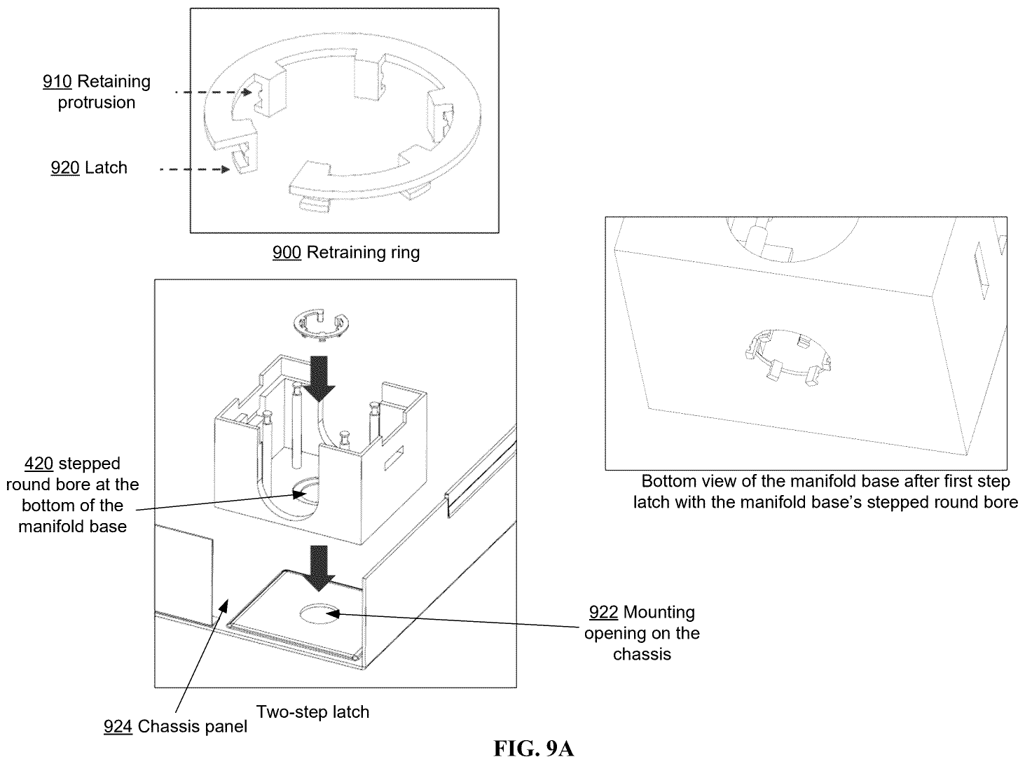

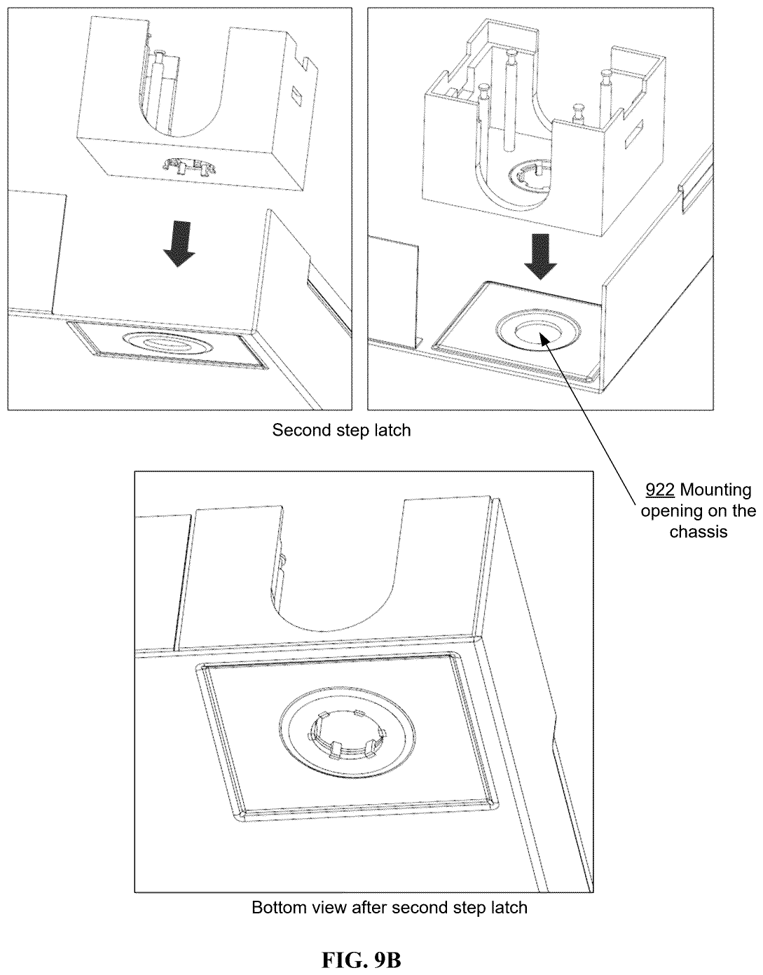

In addition, an optional manifold base-retaining ring 220 may be seated in a stepped round bore on the underside of the manifold base 230 to secure the manifold base 230 to a chassis panel or bracket while allowing tool-less installation. Additional structural and operational details of the manifold base-retaining ring 220 and its two-stage engagement are described with reference to FIGS. 9A and 9B.

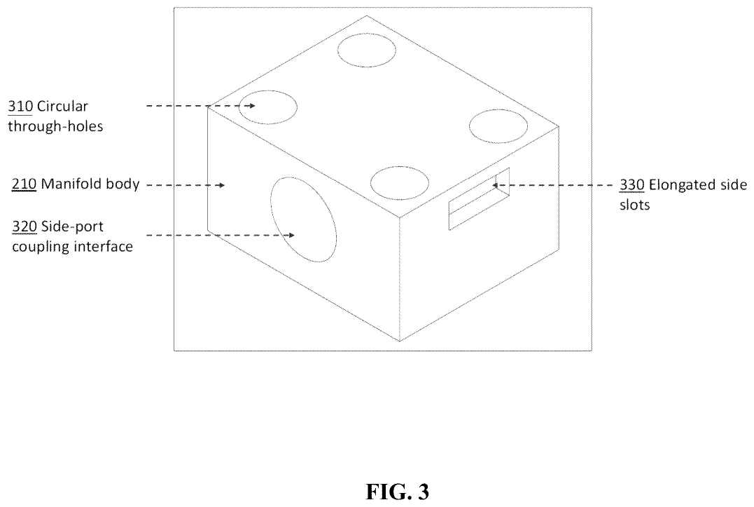

FIG. 3 illustrates an example manifold body 210 of the floating manifold assembly, in accordance with some embodiments. The manifold body 210 is a substantially rectangular block having four circular through-holes 310 that receive the upstanding posts of the manifold base 230. The manifold body 210 further includes elongated side slots 330 used by hooks on sliding plates 200B (shown in FIG. 2) of the top assembly 200 to provide lateral capture; in some embodiments a side slot 330 is provided on each of the two opposing side faces (one shown and one not visible in this view). The manifold body 210 also includes at least one side-port coupling interface 320 configured to accept a mating liquid-cooling fitting and, in common implementations, two opposing interfaces 320 for inlet and outlet connections.

In some embodiments, the coupling interface 320 may be implemented as a female connector geometry suitable for sealing engagement with a mating fitting, such as an internally threaded connector (e.g., straight thread with an O-ring boss or tapered thread), a bayonet-type connector, a quick-connect socket, or a push-to-connect/flat-face style receptacle. The geometry of the interface 320 can be selected to match the coolant standard of the host system while maintaining compatibility with the floating features described herein.

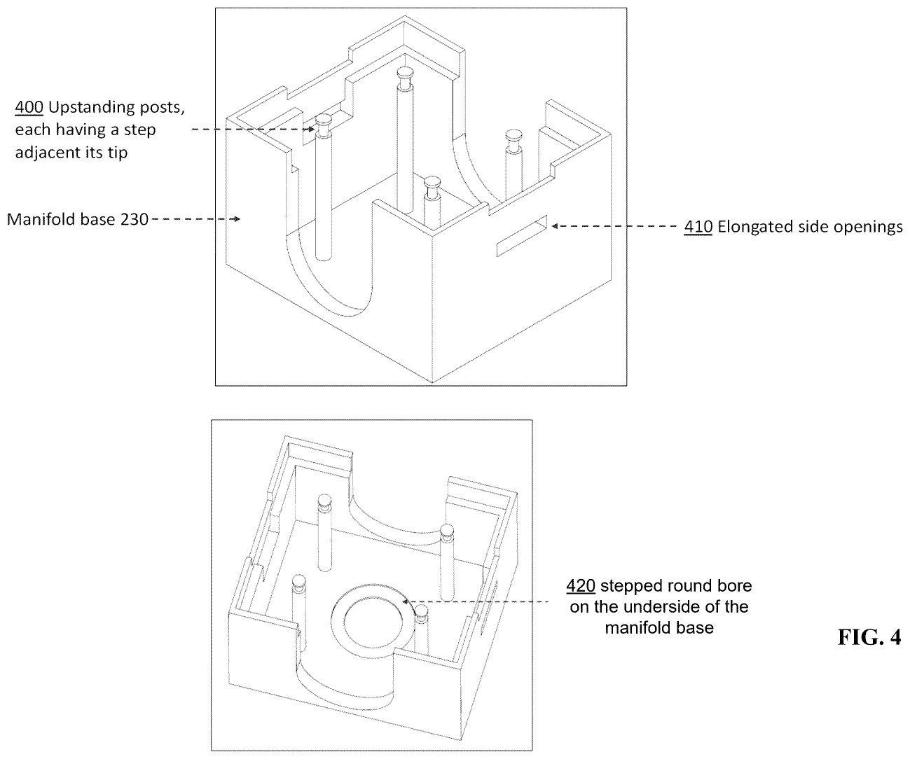

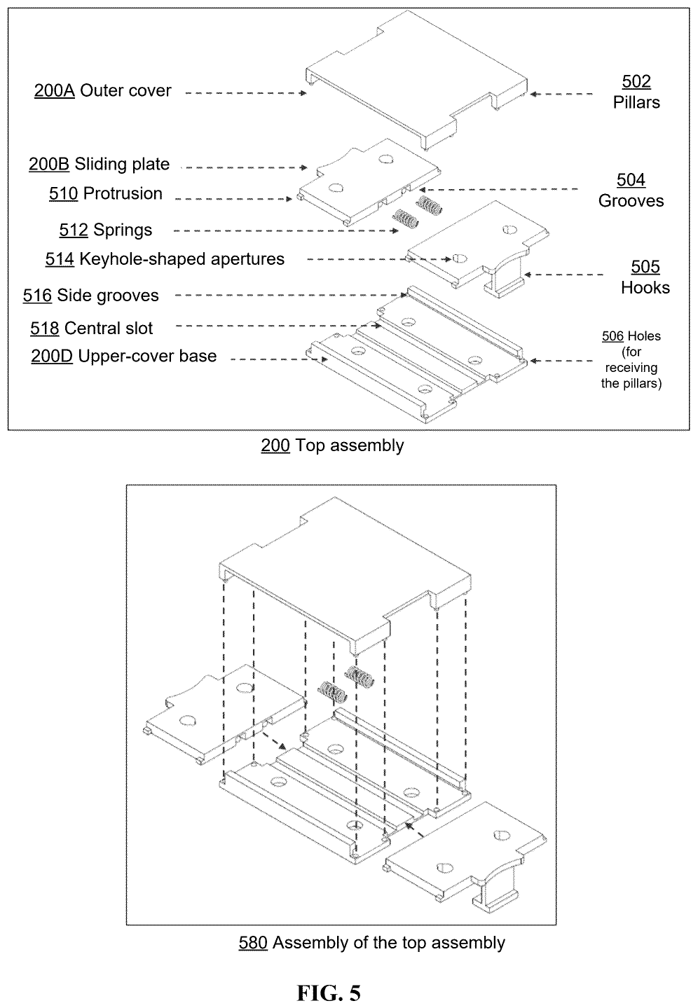

FIG. 4 illustrates an example manifold base 230 of the floating manifold assembly, in accordance with some embodiments. The manifold base 230 includes a plurality of upstanding posts 400 that project from an interior floor and are configured to pass through the circular through-holes 310 of the manifold body 210 in the assembled state. Each upstanding post 400 has a step adjacent its tip that cooperates with keyhole-shaped apertures of the sliding plates 200B (514 in FIG. 5) to retain the top assembly 200 to the manifold base 230 and to bound vertical travel of the manifold body 210 within the enclosure. Opposite sidewalls of the manifold base 230 further define elongated side openings 410 that receive hooks formed on the sliding plates 200B, enabling releasable latching of the top assembly 200 without tools. On the underside of the manifold base 230, a stepped round bore 420 may be provided to seat the manifold base-retaining ring 220, which secures the manifold base 230 to a chassis or bracket while keeping the manifold assembly 250 captured during service operations.

FIG. 5 illustrates an example top assembly 200 of the floating manifold assembly, in accordance with some embodiments. The top assembly 200 includes (from bottom to top) an upper-cover base 200D, two sliding plates 200B, springs 512, and an outer cover 200A. The upper-cover base 200D provides side grooves 516 that guide the sliding plates 200B over a limited stroke and a central slot 518 that locates the springs 512. Each sliding plate 200B carries keyhole-shaped apertures 514 that ride on the stepped tips of the upstanding posts 400 of the manifold base 230 in the assembled system, lateral hooks 505 that releasably engage the elongated side slots 330 of the manifold body 210, and guidance features such as protrusions 510 and cooperating grooves 504 that interface with the side grooves 516 and the central slot 518 of the upper-cover base 200D. The outer cover 200A caps the top assembly 200 and includes pillars 502 that are received in holes 506 of the upper-cover base 200D to secure the top assembly 200 without separate fasteners.

The lower view (label 580) depicts assembly of the top assembly 200. The two sliding plates 200B are inserted from opposite sides along the side grooves 516 of the upper-cover base 200D, the springs 512 are seated in the central slot 518 to bias the sliding plates 200B toward opposite side faces of the manifold body 210 in use, and the outer cover 200A is pressed down so that its pillars 502 register with the holes 506 of the upper-cover base 200D, completing a captive, spring-loaded unit ready to be coupled to the manifold base 230 and the manifold body 210.

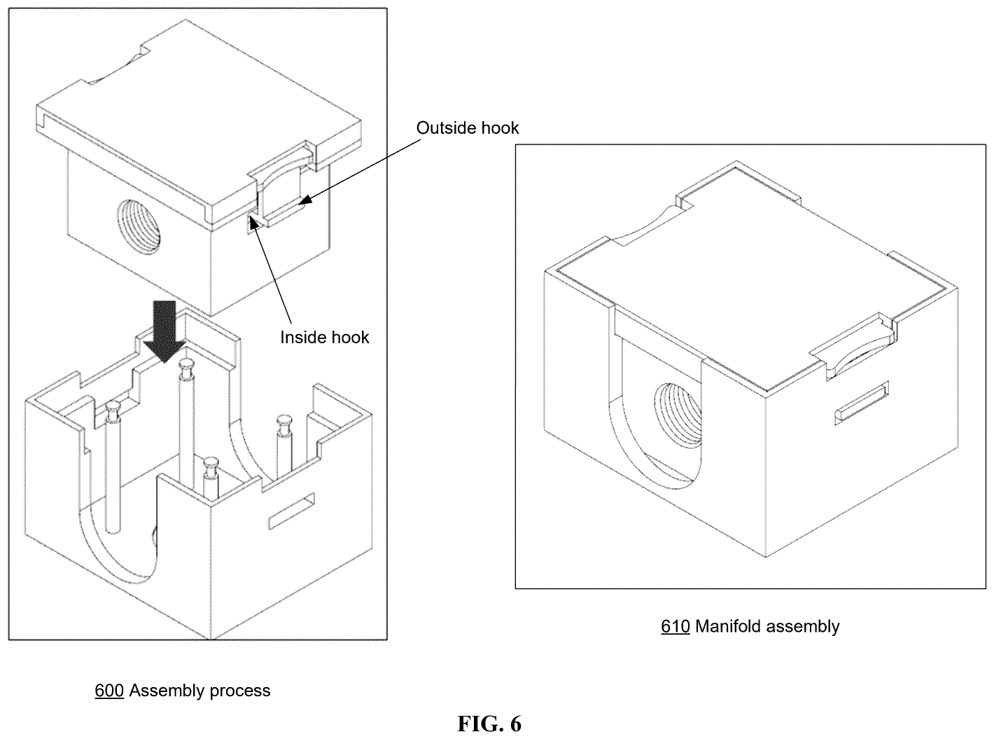

FIG. 6 illustrates an example assembly process for the floating manifold assembly, in accordance with some embodiments. For clarity, reference numerals are omitted in FIG. 6; component numbers correspond to those used in FIGS. 2-5. In a first stage 600, the spring-loaded top assembly 200 is first latched to the manifold body 210 to form a subassembly. This latching is accomplished by the inside-hook of each sliding plate 200B engaging the elongated side slot 330 on the corresponding side of the manifold body 210; the engagement provides lateral capture of the manifold body 210 while leaving vertical clearance intact. The top-assembly&manifold-body subassembly is then lowered into the manifold base 230. As it descends, the upstanding posts 400 of the manifold base 230 enter the circular through-holes 310 of the manifold body 210 and continue into the keyhole-shaped apertures 514 of the sliding plates 200B. When seated, the necked portions of the keyhole apertures 514 settle beneath the steps at the tips of the posts 400 to couple the top assembly 200 to the manifold base 230. At this point the outside-hooks of the sliding plates 200B snap into the elongated side openings 410 of the manifold base 230, providing a releasable latch that secures the subassembly without tools. In the fully assembled state 610, the manifold base 230 and the top assembly 200 together define an enclosure whose height exceeds that of the manifold body 210 to establish controlled vertical clearance, while a designed radial clearance between the posts 400 and the through-holes 310 provides horizontal float.

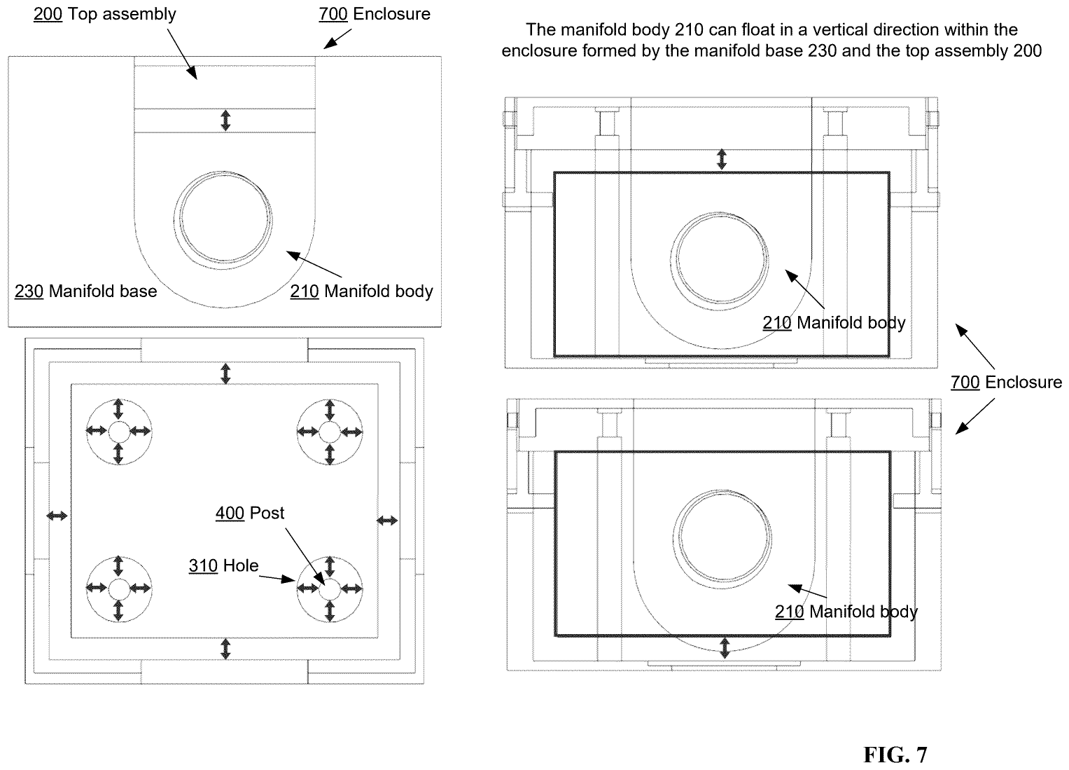

FIG. 7 illustrates example floating clearances in the floating manifold assembly, in accordance with some embodiments. In the upper-left view, the manifold base 230 and the top assembly 200 together form an enclosure 700 whose internal vertical dimension is greater than the height of the manifold body 210. This headroom allows the manifold body 210 to translate in a vertical direction within the enclosure 700, with travel bounded by contact with the underside of the top assembly 200 and the interior floor of the manifold base 230. The upper-right and lower-right cross-sectional views depict this vertical clearance by showing the manifold body 210 at different vertical positions within the enclosure 700.

In the lower-left view, horizontal float is shown. A radial clearance between the upstanding posts 400 of the manifold base 230 and the circular through-holes 310 of the manifold body 210 allows the manifold body 210 to translate side-to-side and front-to-back relative to the manifold base 230. This horizontal motion, together with the vertical clearance described above, enables the manifold body 210 to self-align with mating liquid-cooling fittings during blind mating while remaining captured by the top assembly 200 and the manifold base 230.

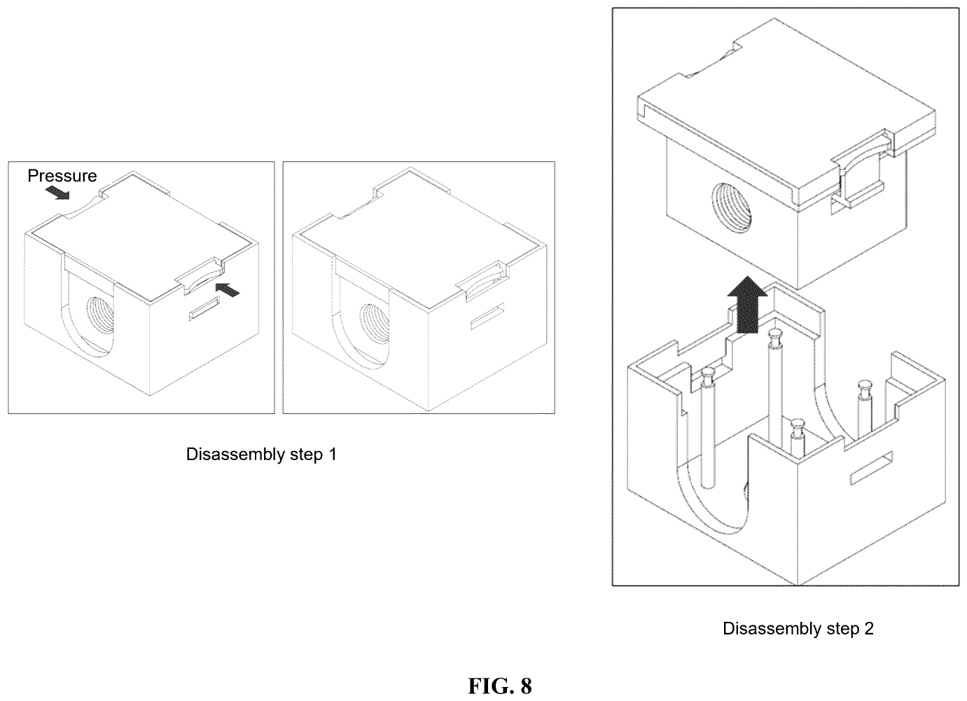

FIG. 8 illustrates an example disassembly process for the floating manifold assembly, in accordance with some embodiments. For clarity, reference numerals are omitted in FIG. 8; component numbers correspond to those used in FIGS. 2-5. In a first step, pressure is applied at the hook locations on the sliding plates 200B to deflect the hooks 505 (more specifically, the outside-hook, with the inside-hook still latched on the manifold body 210) inward and disengage them from the elongated side openings 410 of the manifold base 230. This action does not clamp the manifold body 210; rather, it releases the latch that holds the spring-loaded top assembly 200 to the manifold base 230. With the hooks 505 clear of the elongated side openings 410, the combined subassembly of the top assembly 200 and the manifold body 210 may be lifted upward off the upstanding posts 400, as shown in the second view. If desired for further service, the hooks 505 (more specifically, the inside-hook) can then be disengaged from the elongated side slots 330 of the manifold body 210 to separate the manifold body 210 from the top assembly 200. This tool-less sequence enables quick removal while keeping the manifold body 210 and top assembly 200 captured during handling.

FIGS. 9A and 9B illustrate a manifold base-retaining ring 900 and its cooperation with a stepped round bore 420 on the underside (the chassis-facing lower surface) of the manifold base 230 and with a chassis-panel opening to secure the manifold base 230 tool-lessly. The retaining ring 900 is an annular part carrying multiple circumferentially spaced retaining protrusions 910 and resilient snap latches 920. The stepped round bore 420 in the manifold base 230 is configured with axial shoulders that are engaged by the retaining protrusions 910. The chassis panel 924 provides a mounting opening 922 sized to receive the ring 900; the snap latches 920 are shaped to latch to this mounting opening 922 from the underside of the chassis panel.

In a first stage of attachment (FIG. 9A, lower left), the retaining ring 900 is inserted into the stepped round bore 420 at the bottom of the manifold base 230. As the retaining ring 900 is pressed in, the retaining protrusions 910 ride over a lower shoulder of the bore 420 and snap into engagement with an intermediate step, provisionally capturing the retaining ring 900 within the bore 420 and preventing drop-out during handling. The bottom view at the right of FIG. 9A shows the retaining ring 900 retained at this first step.

In the second stage (FIG. 9B, top views), the manifold base 230 (now carrying the provisionally captured ring 900) is aligned with the mounting opening 922 on the chassis panel and pressed downward until the snap latches 920 engage with the edge of the mounting opening 922 and spring outward beneath the panel. In the fully seated position, the retaining protrusions 910 remain engaged with the step of the bore 420 while the snap latches 920 grip the underside of the chassis panel, so the ring 900 is axially trapped between the bore step and the panel thickness, locking the manifold base 230 to the chassis. The bottom view in FIG. 9B shows the ring 900 fully seated and latched.

For service removal, the process is reversed. A technician accesses the underside of the chassis panel, depresses the snap latches 920 to clear the panel edge, and withdraws the retaining ring 900 from the chassis opening; the ring 900 can then be released from the bore 420 by overcoming the engagement of the retaining protrusions 910. This two-stage mechanism provides a first detent for easy preassembly/alignment and a second detent for robust, vibration-resistant chassis retention-both achieved without separate screws or tools.

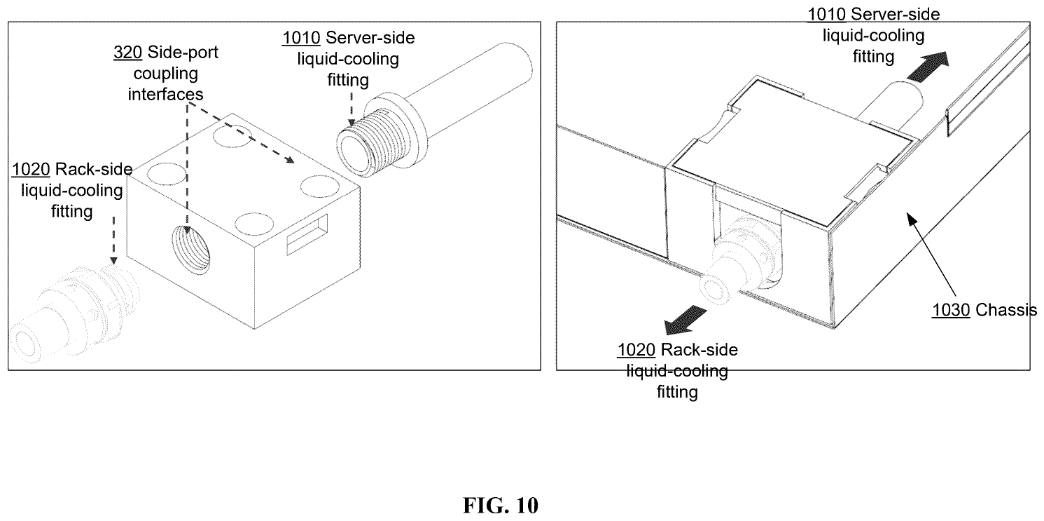

FIG. 10 illustrates an example deployment of the floating manifold assembly, in accordance with some embodiments. In the left view, the manifold body 210 is shown with side-port coupling interfaces 320 implemented, by way of example, as female, internally threaded connectors. A server-side liquid-cooling fitting 1010 and a rack-side liquid-cooling fitting 1020 are depicted as mating male, externally threaded connectors that engage the respective coupling interfaces 320 on opposite sides of the manifold body 210 to complete the server and rack loops. In other embodiments, each coupling interface 320 may be a bayonet receptacle or a quick-connect socket. The right view shows the floating manifold assembly 250 installed within a chassis 1030: as the chassis 1030 is translated along rack rails, the server-side liquid-cooling fitting 1010 and the rack-side liquid-cooling fitting 1020 are guided into sealing engagement with the corresponding coupling interfaces 320. The controlled horizontal and vertical float of the manifold body 210 within the enclosure formed by the manifold base 230 and the top assembly 200 accommodates blind mating, absorbing misalignment and reducing insertion force while protecting sealing surfaces.

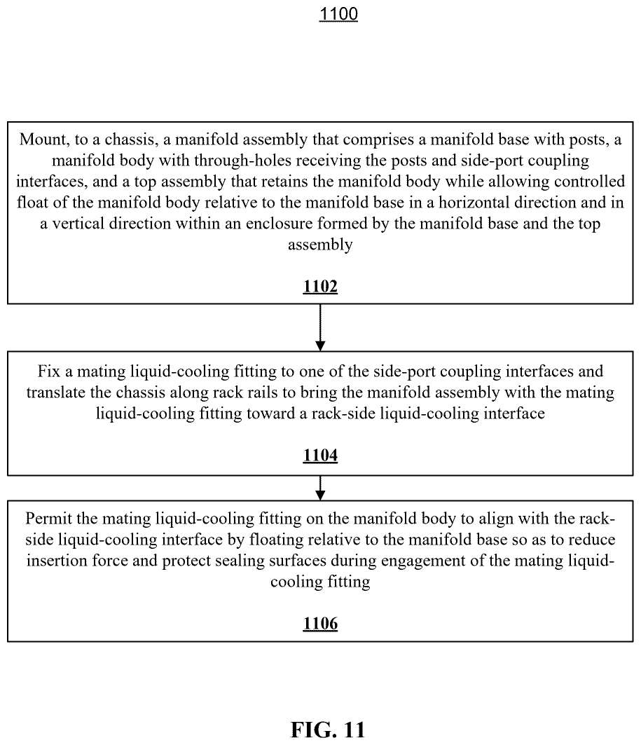

FIG. 11 illustrates an example use of the floating manifold assembly, in accordance with some embodiments. In various implementations, one or more blocks of FIG. 11 may be carried out by an operator, by automated tooling, or by a combination of the two, with or without hand tools.

As shown in FIG. 11, process 1100 begins by mounting, to a chassis, a manifold assembly that includes a manifold base with posts, a manifold body with through-holes receiving the posts and side-port coupling interfaces, and a top assembly that retains the manifold body while allowing controlled float of the manifold body relative to the manifold base in a horizontal direction and in a vertical direction within an enclosure formed by the manifold base and the top assembly (block 1102). This mounting step can be performed by an operator, by automated tooling, or by a combination of the two.

After the manifold assembly is mounted, process 1100 continues by fixing a mating liquid-cooling fitting to one of the side-port coupling interfaces of the manifold body and translating the chassis along rack rails to bring the manifold assembly, with the mating liquid-cooling fitting, toward a stationary rack-side liquid-cooling interface (block 1104). In other words, the fitting on the manifold side moves with the chassis, while the rack-side interface remains fixed to the rack or to rack plumbing.

Process 1100 then includes permitting the mating liquid-cooling fitting on the manifold body to align with the stationary rack-side liquid-cooling interface by floating relative to the manifold base so as to reduce insertion force and protect sealing surfaces during engagement of the mating liquid-cooling fitting (block 1106). Because the manifold body is allowed to float in both horizontal and vertical directions inside the enclosure formed by the manifold base and the top assembly, dimensional variations in the chassis, rails, or rack plumbing can be absorbed without overstressing the fittings.

Process 1100 may include additional implementations, alone or in combination with the foregoing. In one implementation, the hooks of sliding plates of the top assembly are released from elongated openings of the manifold base by applying pressure to remove the top assembly without tools. In another implementation, the controlled float in the horizontal direction is established by a radial clearance between the posts and the through-holes of the manifold body, and the controlled float in the vertical direction is established by clearances between the manifold body and the upper-cover base within the enclosure formed by the manifold base and the top assembly. In a further implementation, the top assembly includes an outer cover having pillars received in corresponding holes of the upper-cover base to cap the top assembly without separate fasteners. In yet another implementation, the manifold base is fixed to the chassis using a retaining ring seated in a stepped bore of the manifold base to secure the manifold base to the chassis during chassis extraction and reinsertion.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A manifold assembly configured to mount within an electronic equipment chassis and to couple liquid-cooling fittings, comprising:
a manifold base comprising a plurality of upstanding posts;
a manifold body captured between the manifold base and a top assembly, the manifold body comprising a plurality of through-holes for receiving the plurality of upstanding posts and at least one coupling interface at a side port to accept a mating liquid-cooling fitting; and
the top assembly coupled with the manifold base and retaining the manifold body while permitting controlled float of the manifold body relative to the manifold base in a horizontal direction and in a vertical direction within an enclosure formed by the manifold base and the top assembly.

2. The manifold assembly of claim 1, wherein the manifold body comprises one or more elongated side slots, and
the top assembly comprises one or more sliding plates each having a hook configured to releasably engage a corresponding one of the one or more elongated side slots to provide lateral capture of the manifold body while maintaining a controlled float.

3. The manifold assembly of claim 1, wherein the top assembly comprises:
an upper-cover base; and
a pair of sliding plates biased by springs seated in the upper-cover base so as to urge the sliding plates toward opposite faces of the manifold body.

4. The manifold assembly of claim 1, wherein each of the plurality of upstanding posts of the manifold base comprises a step adjacent a tip, and
the top assembly comprises keyhole-shaped apertures received over the plurality of upstanding posts and configured to cooperate with the steps to retain the top assembly to the manifold base and to define at least a portion of a vertical travel limit of the manifold body within the enclosure formed by the manifold base and the top assembly.

5. The manifold assembly of claim 1, wherein the manifold base and the top assembly form an internal cavity whose vertical dimension exceeds a height of the manifold body by a designed margin to provide the vertical float within the enclosure.

6. The manifold assembly of claim 1, wherein a radial clearance between the plurality of upstanding posts of the manifold base and the plurality of through-holes of the manifold body is selected to provide the horizontal float to accommodate manufacturing and assembly stack-up tolerances of the liquid-cooling fittings.

7. The manifold assembly of claim 2, wherein the manifold base defines elongated side openings and the hooks of the sliding plates are configured to latch to and be released from the elongated side openings by pressure to enable tool-less removal of the top assembly from the manifold base.

8. The manifold assembly of claim 3, wherein the upper-cover base comprises side grooves that guide translation of the sliding plates over a limited stroke and central slots that locate the springs.

9. The manifold assembly of claim 3, wherein the top assembly further comprises an outer cover having pillars received in corresponding holes of the upper-cover base to cap the top assembly without separate fasteners.

10. The manifold assembly of claim 1, wherein the at least one coupling interface at the side port of the manifold body comprises a female connector geometry selected from the group consisting of an internally threaded connector, a bayonet-type connector, and a quick-connect socket configured for a sealing engagement.

11. The manifold assembly of claim 1, further comprising:
a base-retaining ring disposed in a stepped bore on an underside of the manifold base and configured to fix the manifold base to a surface of the chassis or a bracket.

12. The manifold assembly of claim 4, wherein the keyhole-shaped apertures are formed in a pair of sliding plates and are dimensioned with a neck portion and an enlarged portion to facilitate assembly over the plurality of upstanding posts and retention beneath the steps of the tips of the plurality of upstanding posts.

13. The manifold assembly of claim 1, wherein the controlled float is established by clearances between the plurality of upstanding posts and the plurality of through-holes and by vertical headroom between the manifold body and the upper-cover base within the enclosure formed by the manifold base and the top assembly.

14. The manifold assembly of claim 3, wherein the springs apply a lateral retention force sufficient to maintain engagement between hooks of the top assembly and the manifold body during chassis extraction and reinsertion while avoiding over-constraint that would increase insertion force during blind mating.

15. The manifold assembly of claim 1, wherein the manifold body comprises two opposing side ports each having a coupling interface to accept respective liquid-cooling fittings that connect, in use, to a server-side liquid-cooling loop and a rack-side liquid-cooling loop.

16. A method of facilitating blind mating of liquid-cooling fittings in an electronic equipment rack, comprising:
mounting, to a chassis, a manifold assembly that comprises a manifold base with posts, a manifold body with through-holes receiving the posts and side-port coupling interfaces, and a top assembly that retains the manifold body while allowing controlled float of the manifold body relative to the manifold base in a horizontal direction and in a vertical direction within an enclosure formed by the manifold base and the top assembly;
fixing a mating liquid-cooling fitting to one of the side-port coupling interfaces;
translating the chassis along rack rails to bring the manifold assembly with the mating liquid-cooling fitting toward a rack-side liquid-cooling interface; and
permitting the mating liquid-cooling fitting on the manifold body to align with the rack-side liquid-cooling interface by floating relative to the manifold base.

17. The method of claim 16, further comprising:
releasing hooks of sliding plates of the top assembly from elongated openings of the manifold base by applying pressure to remove the top assembly without tools.

18. The method of claim 16, wherein the controlled float in the horizontal direction is established by a radial clearance between the posts and the through-holes of the manifold body, and
the controlled float in the vertical direction is established by clearances between the manifold body and the upper-cover base within the enclosure formed by the manifold base and the top assembly.

19. The method of claim 16, wherein the top assembly further comprises an outer cover having pillars received in corresponding holes of the upper-cover base to cap the top assembly without separate fasteners.

20. The method of claim 16, further comprising fixing the manifold base to the chassis using a retaining ring seated in a stepped bore of the manifold base to secure the manifold base to the chassis during chassis extraction and reinsertion.
